(19) United States
(12) Patent Application Publication
(10) Pub. No.: US 2010/0148768 A1
(43) Pub. Date: Jun. 17, 2010

(54) METHODS AND APPARATUS FOR PARTICLE DETECTION

(76) Inventor: Ulrich Schwarz, Manchester (GB)

Correspondence Address: Nelson Mullins Riley & Scarborough LLP;IP Department, 100 North Tryon Street, 42nd Floor, Charlotte, NC, 28202-4000, US

(21) Appl. No.: 12/449,940

(22) PCT Filed: Mar. 7, 2008
(86) PCT No.: PCT/GB2008/000805

§ 371 Date: Feb. 18, 2010

(30) Foreign Application Priority Data
Mar. 7, 2007 (GB) 0704359.9

(51) Int. Cl. G01R 33/12

(52) U.S. Cl. 324/239

(57) ABSTRACT

A method of detecting the presence of a substance (32) to be detected on a surface of a substrate (21), the method comprising: i) providing magnetic particles (35) to the substrate (21) for binding with the substance (32) to be detected; and ii) determining the presence of the substance (32) to be detected by detecting the magnetoresistive effect of the magnetic particles (35) bound to the substance (32) to be detected on a magnetoresistive element (40) positioned proximate the substrate surface.

### FIELD OF THE INVENTION

The invention relates to methods and apparatus for the detection of a substance to be detected on a substrate by using magnetic particles. Particular embodiments of the invention are suited for use in detecting biological/chemical substances which may be harmful to health.

### BACKGROUND TO THE INVENTION

Various methods and apparatus for detection of substances using magnetic beads bound to biologically active compounds such as antibodies are known. US 2004/0033627, for example, discloses a method using magnetic beads and electrical circuits to detect chemicals, including an addressable array of detectors on to which detector molecules such as antibodies, proteins, oligonucleotides or other binding molecules are bound. A liquid containing a substance of interest is added to the detector surface, and molecules of the substance to be detected bind to the detector molecules and thus to the substrate surface.

FIG. 1a shows schematically the arrangement of such a detection method. A substrate 11 has a surface 12 on to which detector molecules 13 are bound. A liquid 14 containing a concentration of molecules 15 of a substance to be detected is introduced over the substrate surface 12. An active end 16 of each detector molecule is capable of binding to a molecule 15 of the substance to be detected.

In FIG. 1b the molecules 15 are shown bound to the active ends 16 of a proportion of the detection molecules 13, this proportion typically being dependent upon the concentration of the molecules in the liquid 14.

Shown in FIG. 1c a further liquid 18, containing detection molecules 17a bound on to magnetic particles 17b, is then introduced over the substrate surface 12. These molecules are also capable of binding to the molecules 15 of the substance to be detected.

In FIG. 1d, the detector molecules 17a and magnetic particles 17b are shown bound to the molecules 15 of the substance to be detected, and thereby to the substrate surface 12. By detection of the presence of the magnetic particles 17b proximate the substrate surface 12, an indication of the concentration of the molecules 15 of the substance to be detected in the liquid analyte 14 can be determined.

This general procedure of detection is described in US 2004/0033627, and in other documents such as U.S. Pat. No. 5,981,297, U.S. Pat. No. 5,445,970, U.S. Pat. No. 5,445,971 and WO 97/45740. Each of these describe a substrate that is engineered to actively detect the presence of magnetic particles on its surface. Detection is typically by means of magnetoresistive methods, i.e detecting a change in conductivity of a magnetoresistive material structure within the substrate to determine whether one or more magnetic particles are present in the immediate vicinity of the substrate surface.

The listing or discussion of an apparently prior-published document in this specification should not necessarily be taken as an acknowledgement that the document is part of the state of the art or is common general knowledge.

A problem with the aforementioned methods is that a complex substrate structure, which includes structured layers of different materials, is required to be built up to make the sensor. Typically, the sensor is made for a single use only, since it is made specifically for the detection of a particular type or selection of molecules to be detected, and cannot readily be re-used. For larger detection areas and increased number of detection sites, a more complex array of detectors and associated electronic components needs to be built into the substrate. This increases the cost of the detector.

It is an object of the invention to overcome or alleviate some or all of the aforementioned problems.

### SUMMARY OF THE INVENTION

In accordance with a first aspect, the invention provides a method of detecting the presence of a substance to be detected on a surface of a substrate, the method comprising:
i) providing magnetic particles to the substrate for binding with the substance to be detected; and
ii) determining the presence of the substance to be detected by detecting the magnetoresistive effect of the magnetic particles bound to the substance to be detected on a magnetoresistive element positioned proximate the substrate surface.

In accordance with a second aspect, the invention provides an apparatus for detecting the presence of a substance to be detected on a substrate, the apparatus comprising:
a magnetic field generator configured to apply an external magnetic field to a substrate to provide a magnetoresistive effect on a magnetic reader;
a magnetic reader comprising a magnetoresistive element, the magnetic reader being configured to determine the presence on the substrate surface of the substance to be detected by detecting the magnetoresistive effect of magnetic particles bound to the substance to be detected when the magnetic reader is proximate the bound magnetic particles.

In accordance with a third aspect, the invention provides a kit for the detection of a substance, the kit comprising:
the apparatus of the invention
a container comprising a suspension of magnetic particles labelled with molecules of a labelling compound, the labelling compounds capable of binding to the substance to be detected.

In accordance with a fourth aspect, there is provided a kit comprising one or more control samples for use with the aforementioned apparatus/methods, the control samples for use in providing quantitative measurements of the substance to be detected.

The third and fourth aspects may be provided in one or more combinations, which may or may not include the apparatus of the invention.

The magnetic particles used in the invention can be labelled with one or more labelling compounds. Such labelling compounds may be biological compounds such as antibodies capable of binding to one or more substances to be detected such as virus particles, bacteria or fungal spores. The labelling compounds may alternatively be chemical compounds capable of forming complexes with a substance to be detected such as a drug, metabolite or other chemical compound. The labelling compounds may be bound to the surface of the magnetic particles.

Advantages of the invention may include one or more of the following.

An inexpensive disposable substrate can be used in certain aspects of the invention. These substrates need not contain any magnetoresistive or electronic components, since the detection is performed by applying a magnetoresistive element to the surface of the substrate, the magnetoresistive element forming part of a reader, suitable for analysing a large number of substrates.

Optionally, the magnetoresistive element is scanned across the substrate, i.e. by either moving the substrate relative to the magnetoresistive element or by moving the magnetoresistive element relative to the substrate. The distribution of magnetic particles across the substrate surface can thereby be read by a magnetic reader in an analogous way to reading of information magnetically encoded in, for example, credit cards or magnetic storage disks.

### BRIEF DESCRIPTION OF THE DRAWINGS

Embodiments of the invention will now be described by way of example and with reference to the accompanying drawings, in which

FIGS. 1a to 1d are schematic cross-sectional views of a substance on a substrate illustrating a process of detection;

FIGS. 2a to 2e are schematic cross-sectional views of a substrate illustrating a series of steps of preparation of a detector substrate;

FIGS. 3a to 3e are schematic cross-sectional views of a substrate illustrating schematically a series of steps for preparation of a substrate for measurement of a compound;

FIG. 4 is a schematic cross sectional view of a substrate illustrating an arrangement of a measurement apparatus;

FIG. 5 (prior art) is a schematic cross sectional view of a substrate illustrating an experimental result of the change in resistance of a magnetoresistive element as a function of applied magnetising field;

FIG. 6 is a schematic cross sectional view of a substrate illustrating an experimental result of the change in resistance of a magnetoresistive element proximate a substrate as a function of applied magnetising field;

FIG. 7 is a schematic cross sectional view of a substrate illustrating an arrangement of a measurement apparatus for determining porosity of a substrate;

FIG. 8 is a schematic cross sectional view of a substrate illustrating an alternative arrangement of a measurement apparatus for determining porosity of a substrate;

FIG. 9 is a perspective view of an exemplary method of detection of a compound on a user; and

FIGS. 10-29 show various different aspects and embodiments according to the present invention.

### SPECIFIC DESCRIPTION OF EMBODIMENTS

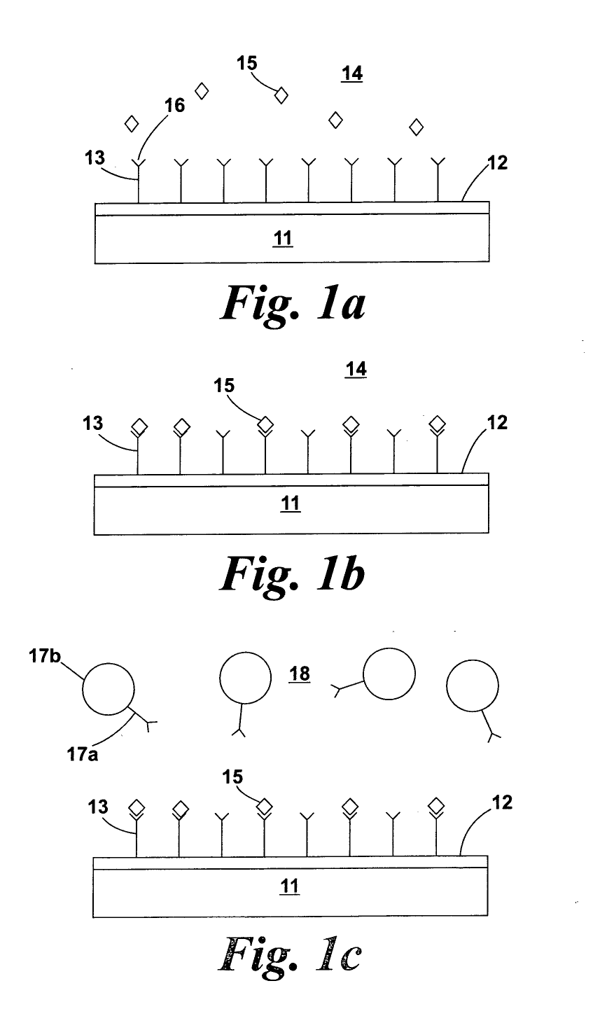

FIGS. 1a to 1d have already been described as part of the background to the invention.

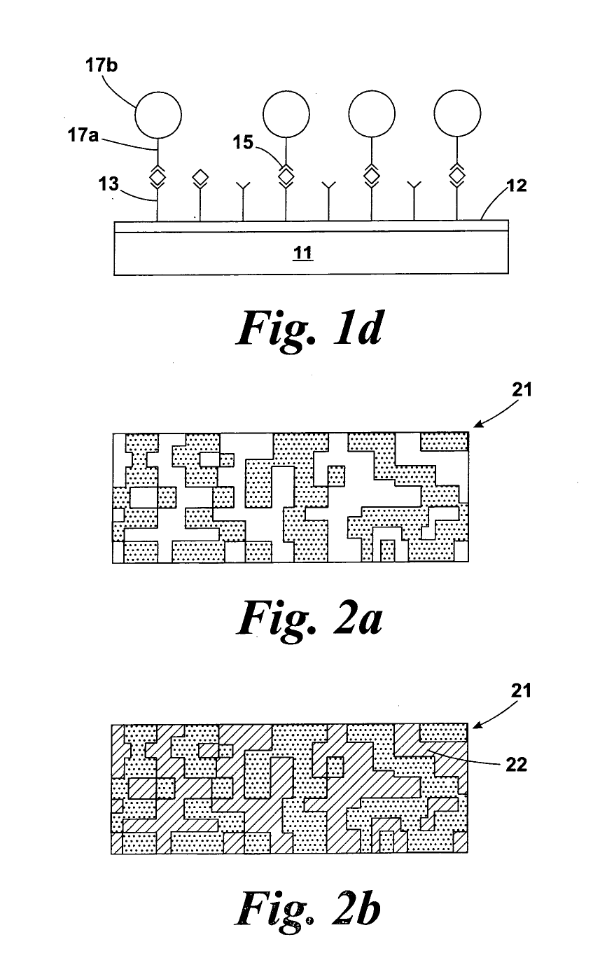

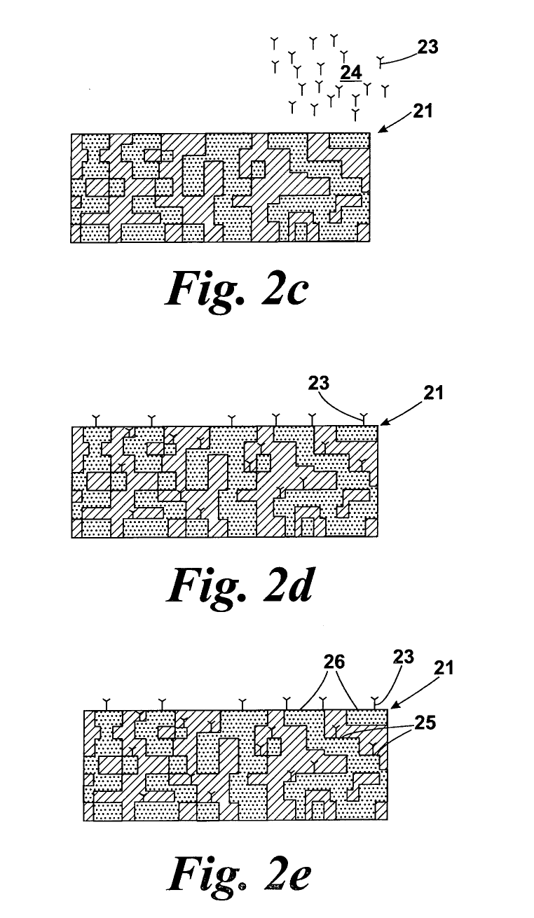

FIGS. 2a to 2e illustrate various steps of a method of preparing a substrate for detection of a compound.

It should be noted that certain embodiments of the present invention are performed directly on the substrates 21 which originally comprise the substance 32 to be detected (e.g. directly on a table surface in a hospital i.e. in situ), but other embodiments are formed on test strips/substrates 21 to which the substance 32 to be detected has been transferred (e.g. taking a sample/swab from the table surface in a hospital and performing the test on the sample/swab) i.e. indirect testing.

A test strip or substrate may be a porous or otherwise bibulous member, for example a nitrocellulose strip. An exemplary porous substrate 21 is illustrated schematically in cross-section in FIG. 2a. The pore size of the substrate is preferably less than 500 nm.

The invention is not, however, intended to be limited to such members. Alternative substrates may be non-porous. Exemplary non-porous substrates may comprise glass or silicon wafers, which may have an advantage of being flat and smooth. A silicon wafer envisaged for use with the invention will typically have a maximum rms surface roughness of less than around 3 nm, and preferably within the range of 1 to 3 nm. A surface of such a silicon wafer may be silanised, i.e. treated with silane (SiH₄) in order to obtain a reactive surface for covalent binding of biological compounds, for example antibodies, which may be monoclonal or polyclonal antibodies. A smooth surface is envisaged to enable improved reading of magnetic beads bound to the surface by a magnetic reader.

In FIG. 2b, the substrate 21 is soaked with a buffer solution 22, for example a 20 mM Tris (2-amino-2-hydroxymethyl-1,3-propanediol), 150 mM NaCl solution at pH 7.2. If the substrate 21 is a silicon wafer, no presoaking stage is required.

In FIG. 2c, a binding compound 23 in the form of a liquid solution 24 is applied to the substrate 21. This binding compound 23 may be a biological compound, for example comprising a monoclonal or polyclonal antibody engineered to bind to a substance 32 to be detected. FIG. 2d shows this binding compound 23 immobilised on the substrate 21. Details of immobilisation of such compounds may be found in, for example, EP 0291194.

The substrate 21 is then dried, leaving a porous membrane loaded with the binding compound, as shown in FIG. 2e.

When a porous membrane is used, some molecules of the binding compound 23 may be bound to surfaces 25 within the inner structure of the membrane, while other molecules will be bound to surfaces 26 close to or on an exterior surface of the membrane.

The dried membrane or substrate 21 shown in FIG. 2e is then ready for use in the following measuring procedure. Use of such dried test strips is known in sandwich immuno assays, for example in pregnancy testing. Such test strips are typically intended for single use only, and are therefore disposable.

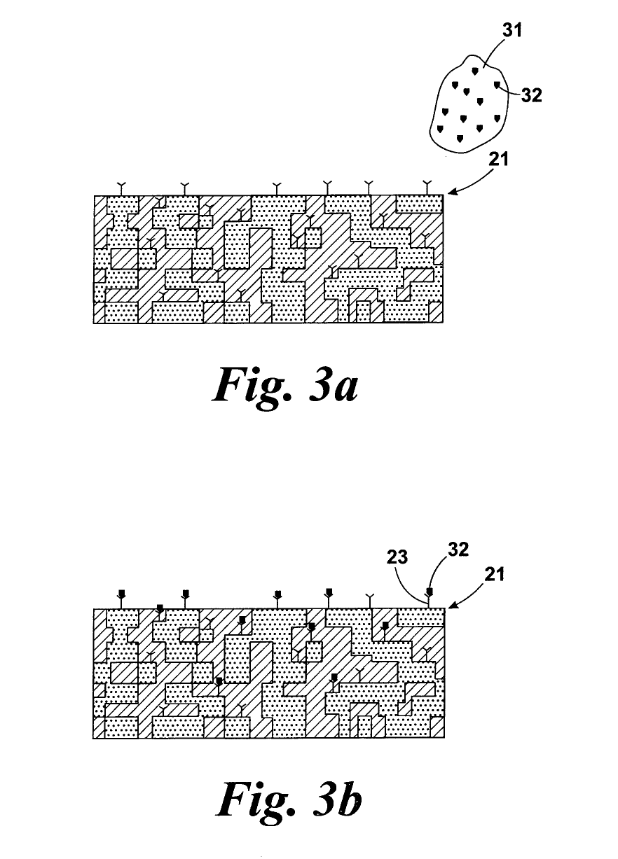

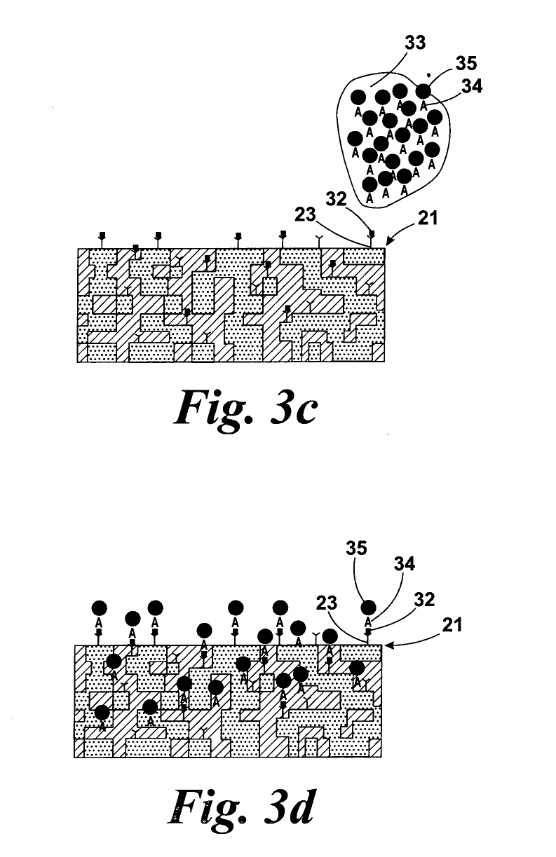

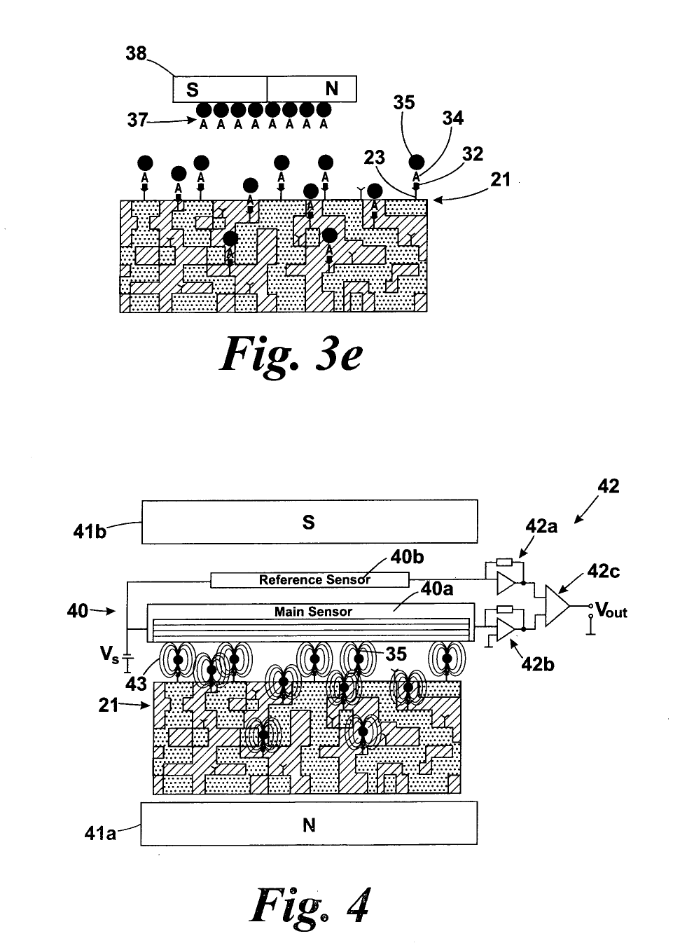

The measurement procedure begins, as shown in FIG. 3a, with the introduction of an analyte solution 31, which may contain a substance 32 to be measured. The solution 31 may, of course, contain no such substance (i.e. measurement yields a negative rather than a positive result), but for the purposes of illustrating the invention the substance 32 is shown (and thus lead to a positive qualitative/quantitative result). Such an analyte solution 31 may be derived from a sample of body fluid such as blood, urine, saliva or other fluid containing a relevant detectable substance. In this example, it will be appreciated that the substance 32 to be detected is not originally present on the substrate 21, but is introduced to the substrate 21.

The substance 32 to be detected is shown in FIG. 3b having now bound to certain molecules of the binding compound 23. The degree of binding, i.e. the proportion of molecules 23 of the binding compound having the substance 32 bound to them will typically be dependent upon the concentration of the substance 32 in the analyte solution 31, although other factors may also influence this.

A further liquid 33 containing a labelling compound 34, molecules of which are bound to magnetic particles 35, is then introduced to the substrate 21, as shown in FIG. 3c. Molecules of the labelling compound 34 may be attached to the magnetic particles as is known in the art, for example as described in US 2004/0106121 or in US 2004/0033627. For clarity, only one magnetic particle for each molecule of the binding compound 23 is shown in this and subsequent figures. However, it should be understood that typically more than one molecule will be attached to each magnetic particle 35. Also, the magnetic particles 35, although small, may be orders of magnitude larger than the molecules (of the binding compound 23) bound on to them.

The labelling compound 34 may be the same as, or different to, the binding compound 23. If different, the compounds may be capable of binding to different sites present on the substance 32 to be detected. The binding 23 and labelling 34 compounds may be capable of binding to the different surfaces present on the substrate 21 and the magnetic particles 35.

The molecules of the labelling compound 34 bind on to the substance 32 to be detected as the liquid 33 covers the substrate 21, as shown in FIG. 3d. Each bound molecule 34 of the labelling compound forms a sandwich with the substance 32 to be detected and a molecule 23 of the binding compound, similar to the arrangement shown in FIG. 1d.

Molecules of the labelling compound 34 that are not bound to any of the substance 32 to be detected are then removed from the substrate 21, as shown in FIG. 3e. Removal may be achieved by the application of an external magnetic field. In FIG. 3e this removal step is indicated schematically by the application of a magnet 38, which attracts to it the magnetic particles having molecules 37 of the labelling compound 34 that have not been bound to the substance 32 to be detected. In practice, at least for particles comprising a paramagnetic material, a magnetic field gradient (which may be created by an electromagnet) applied to the substrate 21 needs to be sufficiently strong to cause the free molecules 37 to be removed from the substrate 21, while being insufficiently strong to substantially affect the bound molecules of the labelling compound 34. Alternatively, or additionally, a washing stage may be included to remove free molecules 37 from the substrate 21.

To perform a measurement, the substrate 21 is brought into close proximity or contact with a magnetic field sensor such as a magnetoresistive element 40, as shown in FIG. 4. To obtain the best reading, a distance between a main sensor 40a of the element 40 and the surface of the substrate 21 should be as small as possible. It is estimated that a distance of 0.2 times the average radius of the magnetic particles 35 is optimum for obtaining a readable signal from the element 40.

The magnetoresistive element 40 may comprise a reference sensor 40b and a main sensor 40a, the main sensor 40a being closer to the surface of the substrate 21. By measuring the difference in conductance between these sensors 40a, 40b, a sensitive measurement can be made of the contribution made by the local magnetic fields 43 of the magnetic particles 35 bound to the substrate 21. The conductance may, for example, be determined by applying a supply voltage Vₛ across each sensor 40a, 40b and measuring a change in current through each sensor using appropriate electronics 42.

It will be appreciated that magnetoresistance is the property of a material to change its electrical resistance due to the application of an external magnetic field. In the present case, it will be appreciated that the presence of a magnetic field external (e.g. due to the magnetic particles 35 or some other (e.g. additional) external magnetic field) will result in a differential change in the resistance (and thus conductance) detected by the main/reference sensor 40a/b. The difference in conductance detected by the main and reference sensors 40a/b is by virtue of the difference in proximity of the main and reference sensors 40 a/b to the magnetic particles 35.

In certain cases, an external magnetic field is applied to the substrate 21, for example as applied by two poles 41a, 41b of a magnet, which may be an electromagnet. The external magnetic field may be applied to the substrate 21 such that the magnetic field lines are aligned in a general direction orthogonal to the plane of the substrate, as in the case of the illustration of FIG. 4. Other orientations may however alternatively be applied. The application of this external magnetic field can be used to enable the magnetoresistive effect to be used, under practical conditions, for sensitive measurement of the presence of magnetic particles 35.

With the application of this external magnetic field, the magnetic particles 35 are affected according to the type of magnetic material the particles 35 are made from. If the particles 35 are substantially paramagnetic or diamagnetic, local magnetic fields 43 are set up around each particle 35 as the external magnetic field is applied, these local magnetic fields 43 falling back to zero once the external magnetic field is removed. If the particles 35 are substantially ferromagnetic, local magnetic fields 43 around each particle may persist once the applied magnetic field is removed.

Both effects may be detected by the magnetoresistive element 40. Time dependent effects on the magnetisation properties of the particles 35 may also or alternatively be used to detect their presence, for example by quickly removing the external magnetic field and observing a slower decay in the local magnetic fields 42.

The electronics 42 connected to the magnetoresistive element 40 may include current to voltage converters 42a, 42b, one for each of the reference sensor 40b and main sensor 40a, and a differential amplifier 42c, in order to measure the small changes in conductance between the reference sensor 40b and main sensor 40a. An output Vₒᵤₜ from the differential amplifier is dependent upon the density of magnetic particles 35 present on or near the surface of the substrate 21.

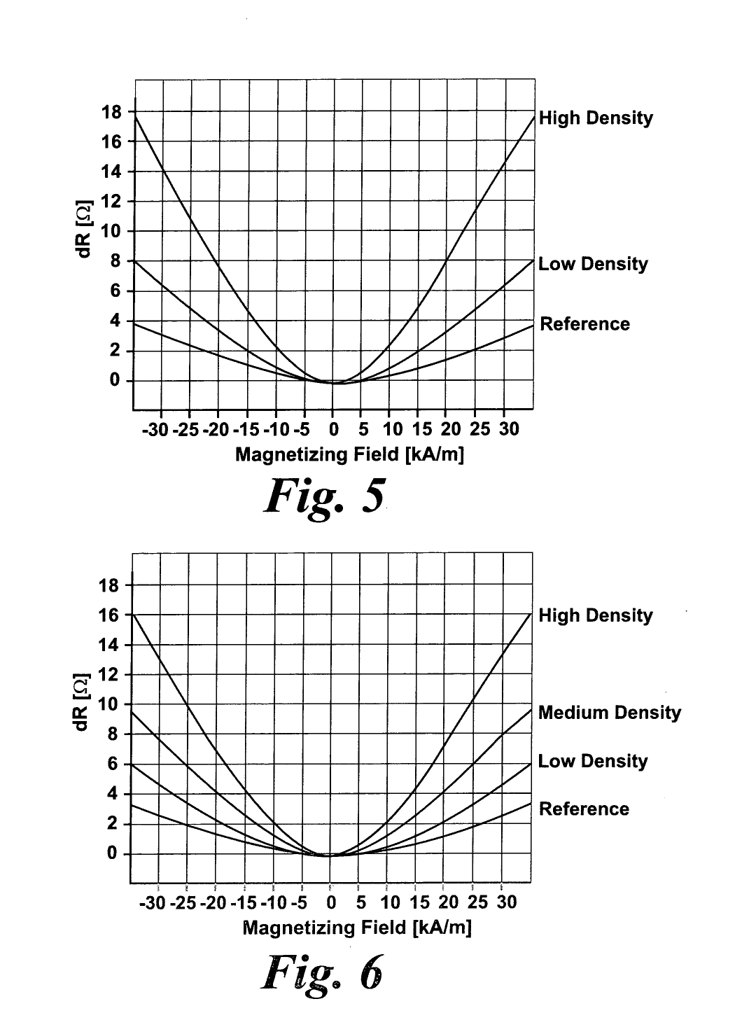

FIG. 5 shows the result of a series of measurements taken from a magnetoresistive element when paramagnetic beads were placed on a GMR (giant magnetoresistive) sensor surface (according to the prior art). For different densities of beads on the sensor surface, the densities ranging from no beads (reference) to low density and high density, different levels of paramagnetic response were detected, shown as a variation in the value of dR, measured in Ohms (Ω), i.e. change in resistance of the magnetoresistive element, as a function of applied magnetising field, measured in kA/m (1 kA/m=1 Gauss=10⁻⁴ Tesla). As can be seen from the results, a clear difference in response to magnetising field is evident as a function of the density of magnetic particles present.

FIG. 6 shows the results of a test measurement performed on a test strip surface comprising a nitrocellulose filter disk substrate 21 with a pore size of approximately 50 nm. A magnetoresistive sensor brought close to the test strip surface was able to sense a range of density of magnetic beads on the test strip, the density ranging from no beads (reference) to a high density of beads. These measurements were carried out on a wet surface, and this therefore indicates that good signal intensities can be achieved without a need for drying the substrate 21 before analysis using the magnetoresistive element 40.

The above tests have indicated that a detection level limit for the method is of the order of ng/l, or alternatively within the picomolar range, for example around 4.2 pM. This compares well with other methods such as typical sandwich immuno assay methods or PCR methods, which may typically be 10-1000 times less sensitive.

In contrast to prior art solutions, in which the paramagnetic beads are bound to the surface of a magnetoresistive sensor, the present invention allows for detection of the presence of paramagnetic beads on the surface of a substrate by bringing a sensor into close proximity with the substrate. The principle may be compared to that of a computer hard disk drive.

A Giant Magnetoresistive (GMR) sensor can detect a single paramagnetic bead of any size as long as the following conditions are met:
1) the sensor is about or at least the same size as the bead,
2) the bead surface is about 0.2 bead radii away from the surface of the sensor,
3) the bead has a χm of 0.05 (where χm is the dimensionless magnetic susceptibility), and
4) the GMR sensor response is adequate.

All four of these conditions may be presently met at a bead radius, r, of around 500 nm. Reducing the bead radius further, e.g. to 100 nm, may be possible as magnetoresistive sensor technology improves.

In a general aspect therefore, the magnetic particles of the invention may have a radius of around 500 nm, or may have a radius no greater than 500 nm. The magnetic particles may have a radius within the range of 100 to 500 nm. The magnetic particles may comprise a material having a magnetic susceptibility of around 0.05 or greater.

A thin passivation layer may be provided covering the magnetoresistive sensor 40 to allow the sensor to better withstand chemical treatments and saline environments in an assay according to certain aspects of the invention.

Other types of magnetoresistive sensors may be used in accordance with the invention, such as sensors utilising the known effects of colossal magnetoresistance (CMR) or magnetic tunnel effect (TMR).

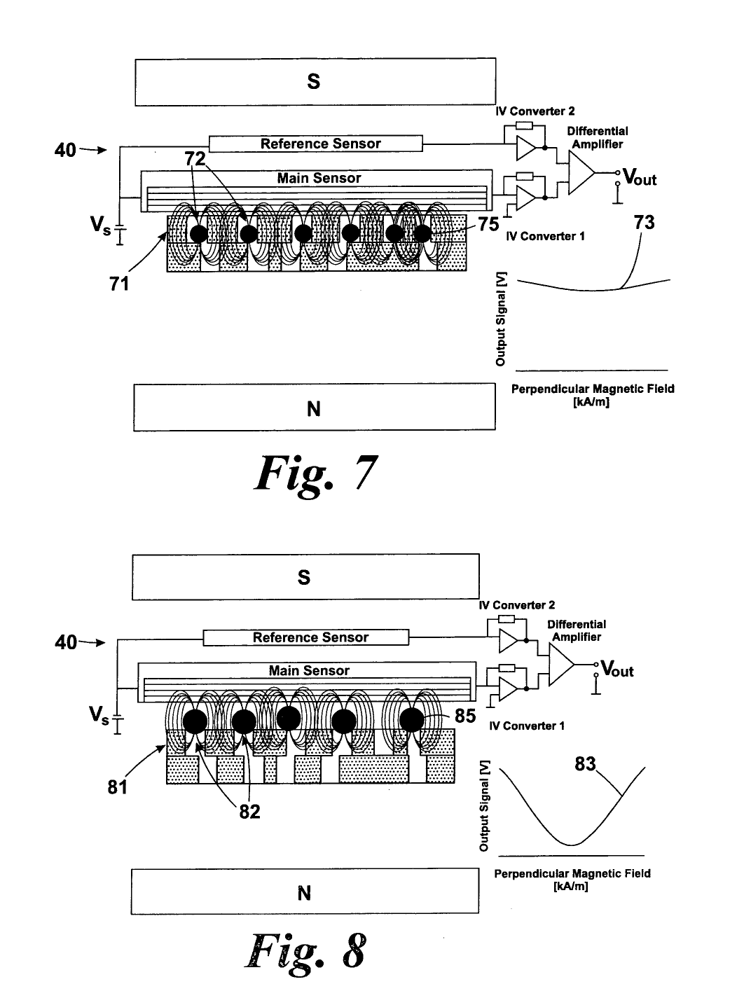

Aspects of the invention may be used to determine pore size of a porous substrate. Shown in FIG. 7 is a schematic cross-sectional view of an apparatus for determining pore size of a substrate 71. Pores 72 in the substrate surface are of a size to accommodate magnetic particles 75. In this embodiment, the magnetic particles 75 have a diameter smaller than pores 72 in the surface of the substrate 71. An output signal 73 as read from the sensor 40 is shown, indicating that the particles 75 are within, rather than on the surface of, the substrate 71.

An alternative embodiment is shown in FIG. 8, in which magnetic particles 85 have a diameter larger than pores 82 in the surface of the substrate 81. An output signal 83 is shown, indicating that the particles 85 are on the surface of the substrate 81 rather than within the pores 82.

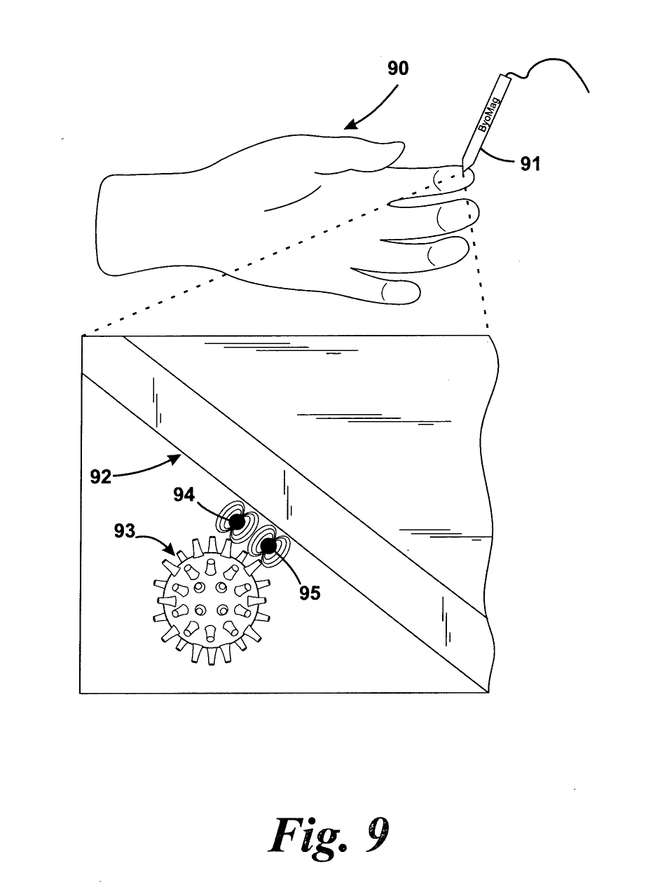

An embodiment of another aspect of the invention is illustrated in FIG. 9, in which is illustrated a method of detecting magnetic particles on a substrate, the substrate in this illustrative example being fingertips of a hand 90 of a user. A magnetoresistive sensor 91 is brought into close contact with the substrate 90 to detect magnetic particles 95 thereon. In this example, the magnetic particles 95 are bound to a virus particle 93 via molecules of a labelling compound 94 bound to the magnetic particles 95 and to the virus particle 93. In this or other embodiments the magnetic particles 95 may bind by adsorption to the substrate surface, e.g. by electrostatic, Van der Weals forces or by forming binding complexes.

Aspects of the invention can be utilised in, for example, the food or health industry to detect fungal, microbial (e.g. bacterial) or viral contamination. A kit comprising a magnetic sensor and a dispensing container holding a liquid suspension of labelled magnetic beads may be employed to test for contamination on a surface. The magnetic sensor may be a handheld sensor, i.e. a hand-portable and optionally self-contained unit. The magnetic sensor preferably comprises the sensor, magnetic and electronic components shown in FIG. 4 and described above.

In a first step, the surface to be examined is brought into contact with magnetic beads labelled with a monoclonal or polyclonal antibody. The labelled beads are brought into contact for example by applying a liquid suspension of the beads to the surface. The antibody, which may be at least one monoclonal antibody and/or at least one polyclonal serum (suitable antibodies being commercially available from e.g. Sigma-Aldrich Company Ltd.), may be specific for the microbial or viral species to be detected, for example Listeria or MRSA (Methicillin-resistant Staphylococcus aureus). Two or more different antibodies, each capable of binding to different sites, may be used. To the extent that the species to be detected is present, the magnetic beads are bound to the microbial or viral particles. Excess (i.e. unbound) beads may be removed by using a washing solution, optionally in combination with an applied magnetic field. Any bound beads may be detected by applying the sensor 91 to the substrate surface.

The inducing magnetic field, i.e. a field necessary to cause paramagnetic or diamagnetic particles to generate their own magnetic field, may be applied parallel to the surface of the substrate. This inducing external magnetic field may not necessarily be required for certain ferromagnetic magnetic particles 35.

An alternative embodiment includes a method of “competitive assaying” of a substance 32 in an analyte 31. In this method, a labelling compound 34, bound on to magnetic beads 35, is incubated with the analyte 31. The labelling compound 34, which may be a protein complex, is capable of binding to the substance 32 to be detected in the analyte 31. Binding sites on the labelling compound 34 are thereby blocked by the presence of the substance 32. The beads 35 are then applied over the surface of a non-porous substrate 21, on which is bound a binding compound 23, which is capable of binding to the same binding sites on the substance as the labelling compound 34. The number of beads 35 bound to the surface of the substrate 21 will therefore depend on the concentration of the substance present in the analyte 31, i.e. the more beads 35 bound to the surface the lesser the concentration of the substance 32.

It is to be understood that the term “substrate” is intended to encompass articles having a surface that can be used in conjunction with one or more aspects of the invention, including but not intended to be limited to: porous and non-porous membranes or wafers; walls, floors and furniture, including hospital equipment; hands and other parts of the body; and articles of clothing.

As described above, magnetic particles for use with aspects of the invention may be labelled with monoclonal and/or polyclonal antibodies capable of binding to a particular compound 32 to be detected. The magnetic particles 35 may alternatively be labelled with chemical complexes capable of binding to a particular compound 32 to be detected, for example for the detection of illicit drugs. The term “labelling compound” is therefore intended to encompass biological compounds as well as chemical compounds.

Labelling compounds 34 and/or binding compounds 23 as described herein may comprise mixtures of monoclonal antibodies. It will be appreciated that, dependent on appropriate control experiments, the aforementioned techniques can be used to provide quantitative as well as qualitative determination of the presence of the substance to be detected. For example, test swabs/substrates (or other control samples) may be supplied with known amounts of the substance to be detected and/or known amounts of the magnetic particles attached to the substance to be detected for use as controls. Such control samples (e.g. test swabs/substrates) may be provided for different substrate surfaces and/or different concentrations of the substance to be detected in the analyte, and may be in liquid and/or solid (e.g. powdered amounts of the substance to be detected; magnetic particles for binding or bound to the substance to be detected, labelling compound, and/or binding compound) form.

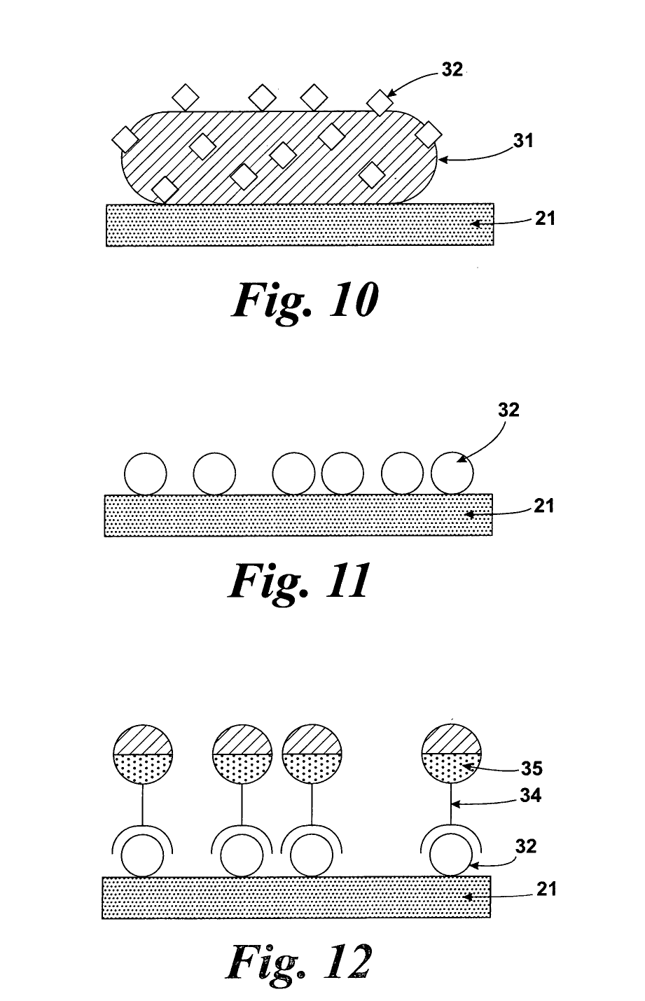

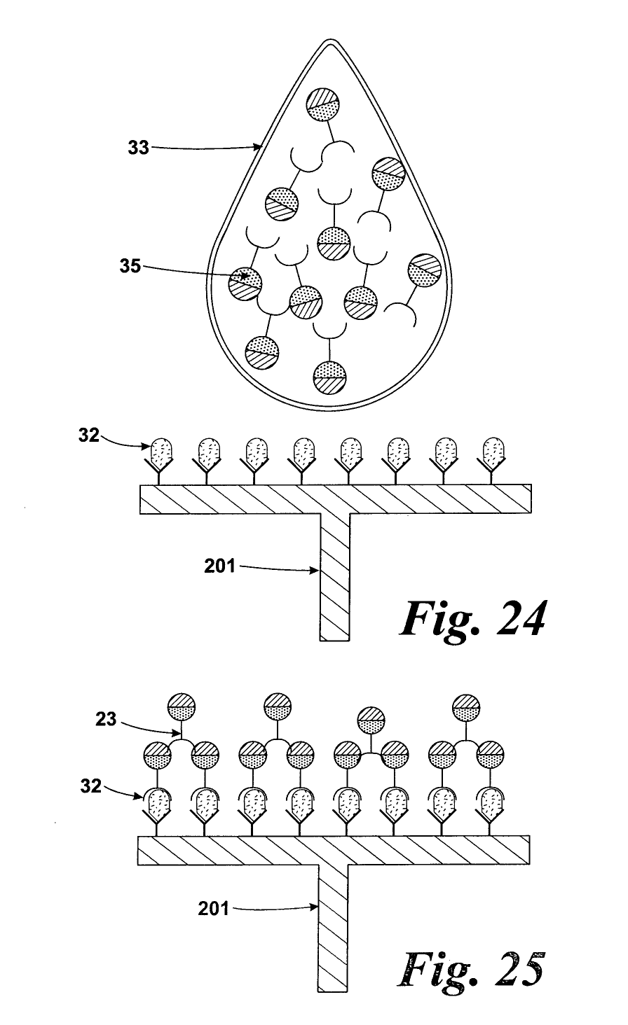

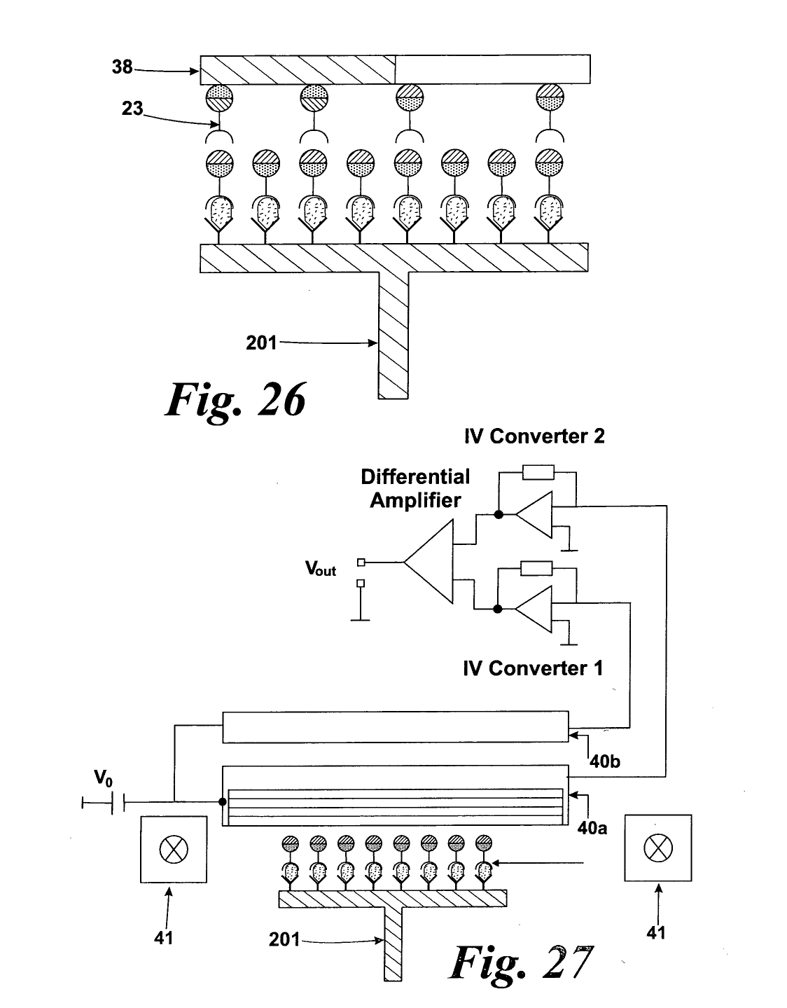

A few further embodiments of the invention are shown in FIGS. 10 to 29, with corresponding reference numerals.

In FIGS. 10 and 11, the substrate 21 is a surface in a hospital. In the case of FIG. 10, the analyte 31 can be considered to be a micro-organism, which is indirectly detected by using antigens 32 on the outer bacterial membrane. The invention detects the antigens and thereby detects the presence of the micro-organism. Alternatively, the micro-organism can, in effect, be considered to be the substance to be detected which is indirectly detected by binding magnetic particles to the antigens 32 on outer membrane of the micro-organism 31.

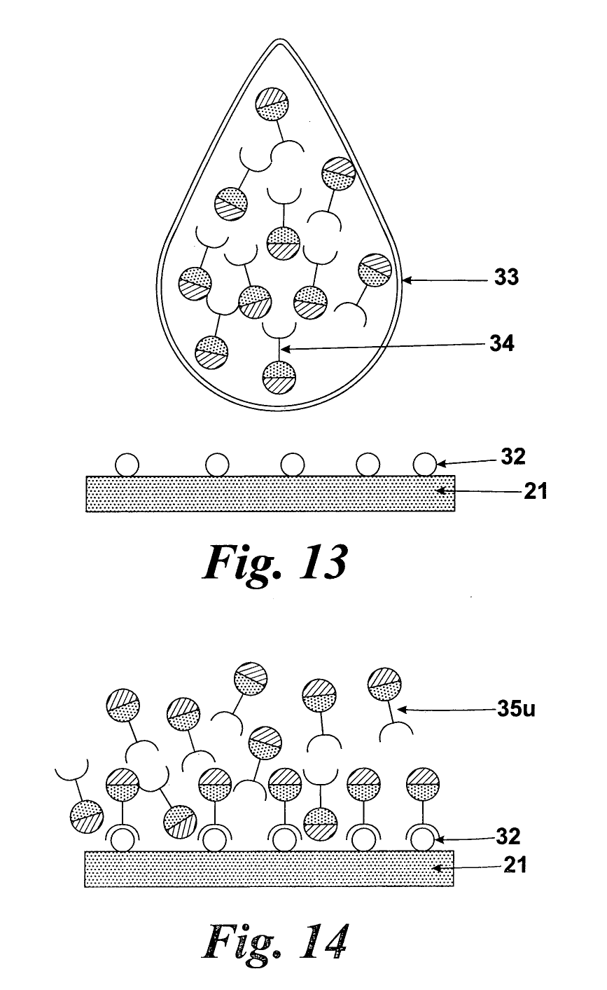

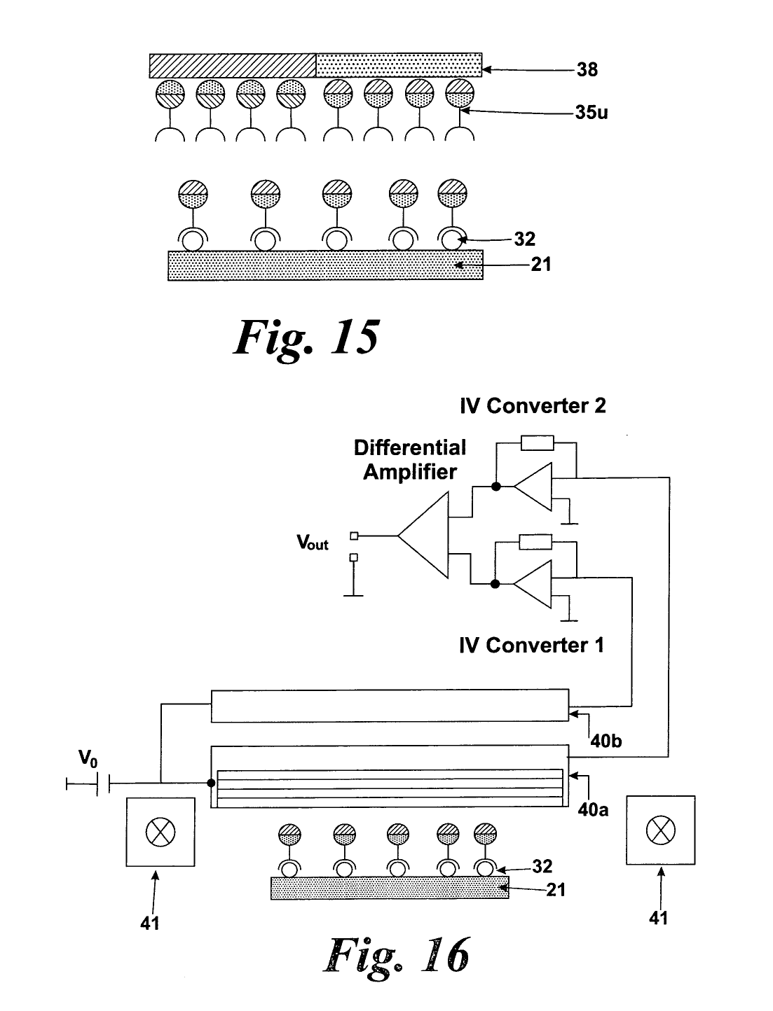

In the case of FIG. 11, the analyte/substance to be detected 31/32 can be considered to be one or more of a protein, DNA, lipids, etc. As shown in FIG. 12, monoclonal antibodies (labelling compound) 34 are used to bind magnetic particles 35 to the substance 32 to be detected. This is done (FIGS. 13, 14 and 15) by the prior application of a reagent 33, comprising magnetic labelled monoclonal antibodies to the substance 32 to be detected. This provides some magnetic particles 35 which are bound to the substance 32 to be detected and others 35u which are not (FIG. 14). These unbound magnetic particles 35u can be removed by the application of a magnet (FIG. 15).

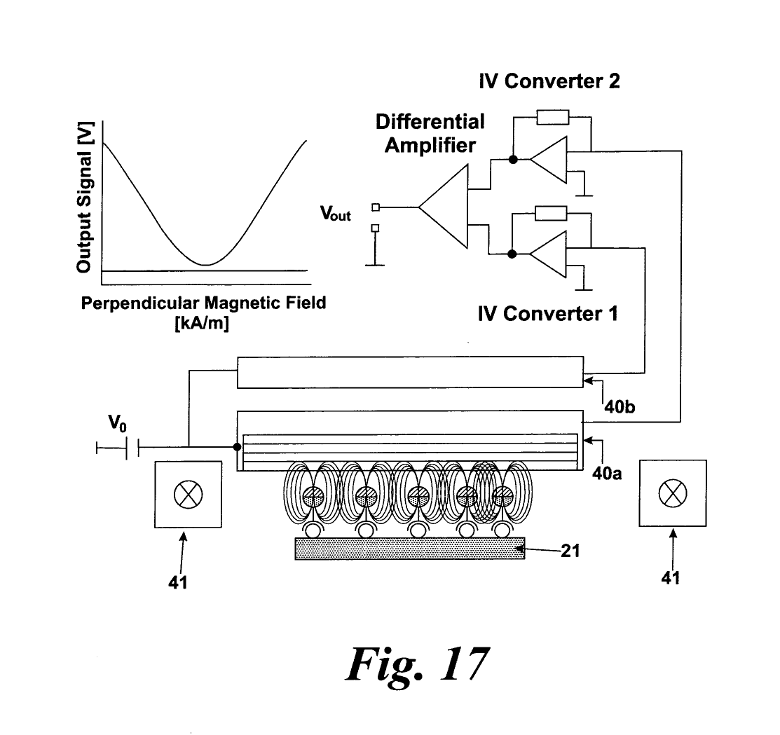

Then, a GMR sensor 40 (or magnetoresistive element) is brought into proximity with the surface of the substrate 21 comprising the bound magnetic particles (FIG. 16). In this case, a circular coil 41 is used to apply an external magnetic field perpendicular to the sensor 40. As shown in FIG. 17, the application of the external magnetic field induces a sufficient magnetic field in the magnetic particles 35, the presence of which is detected by the sensor 40 by virtue of a magnetoresistive effect. The plus/minus parts of the magnetic field are caused by changing the direction of current flow in the coil 41 used to generate the external magnetic field.

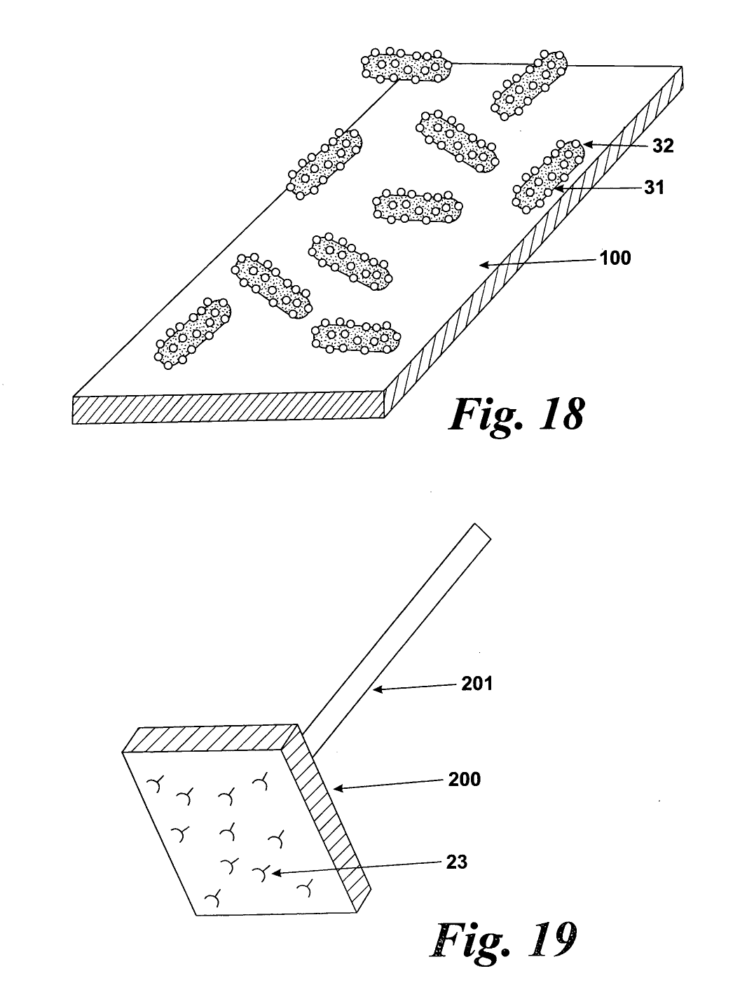

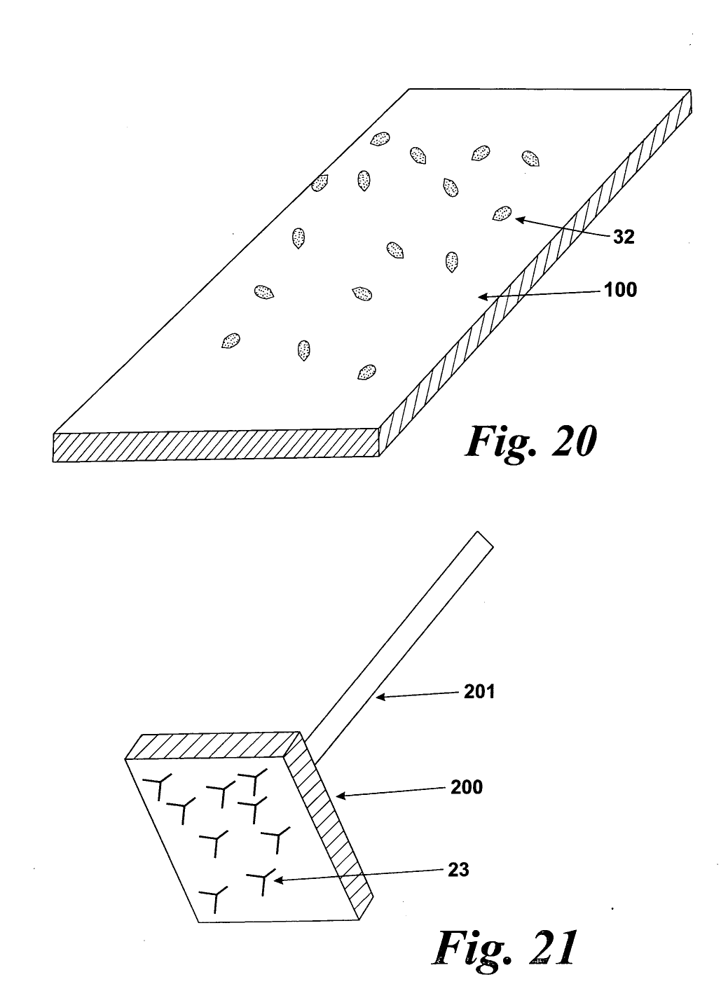

FIGS. 18 and 20 show test surfaces 100 which are respectively swabbed using swabs 19 and 21 to collect the substance to be detected. In the case of FIG. 18, the substance to be detected is a micro-organism (similar to FIG. 10), and in the case of FIG. 20, the substance to be detected is a protein, DNA, lipid etc (similar to FIG. 11). However, unlike FIGS. 10 and 11, the measurements are not performed directly on the surfaces 100, but on swabs 200. As shown in FIGS. 19 and 21, the swabs 200 comprise a collecting surface (and a handle 201), the collecting surface/substrate comprising a suitable binding compound 23 to bind with, and thus collect, the particular substance 32 to be detected. The binding compound 23 is an immobilized monoclonal antibody specific for the substance 32 to be detected.

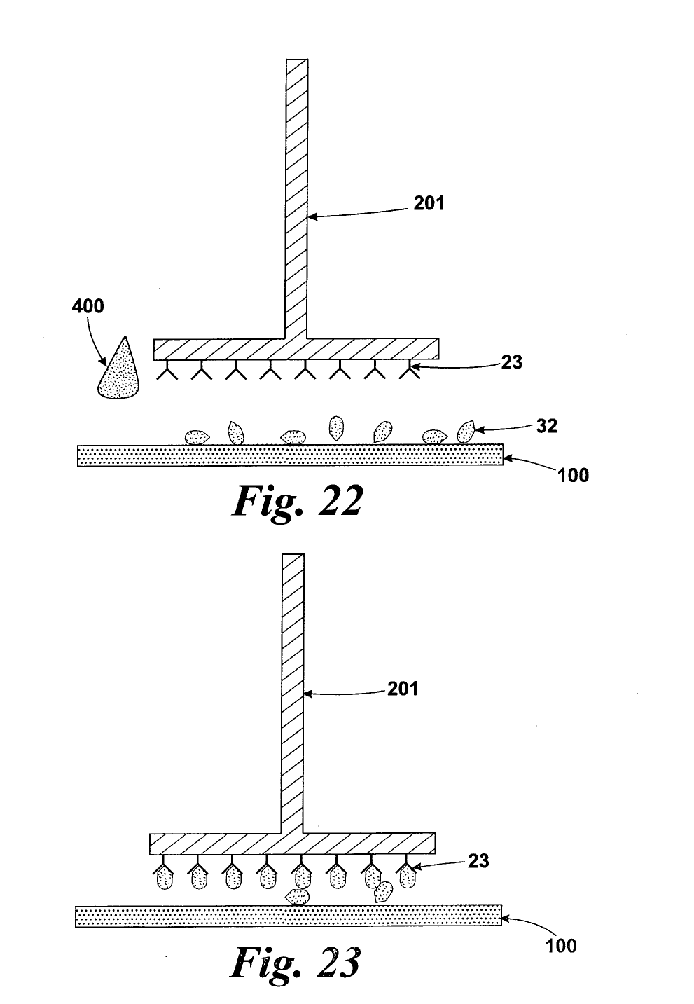

The collection and detection process can be seen for the embodiment of FIGS. 20 and 21 in the subsequent figures. In particular, the collection process is shown in FIGS. 22 and 23. A collecting buffer 400 (FIG. 22) may be used to aid collection of the substance to be detected onto the swab 200.

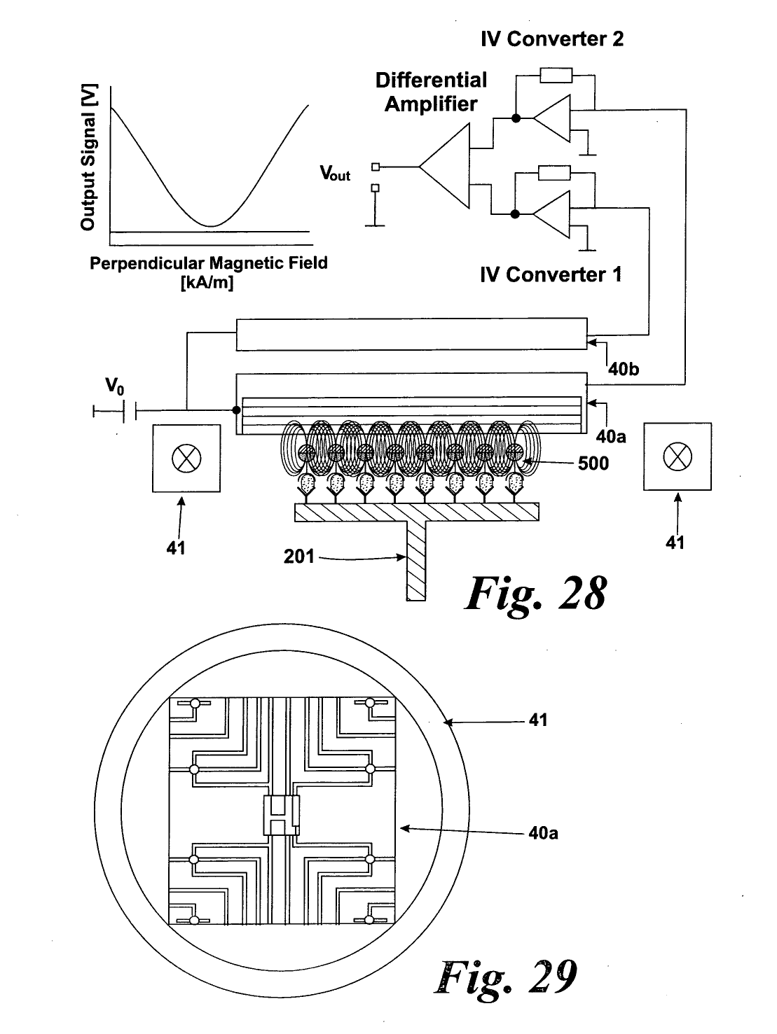

Similar to the embodiments of FIGS. 13-15, the embodiments shown in FIGS. 24-26 provide the magnetic particles 35 so that at least some of them bind to the substance 32 to be detected. Again, the presence of the bound magnetic particles 35 are detected using an externally applied magnetic field 41 (a electromagnetic coil is used) to provide a magnetic field 500 for the magnetic particles 35 which is sufficient to cause an magnetoresistive effect on a proximal sensor 40 (FIGS. 27-28). A bottom view of a GMR sensor 40 (main sensor 40a) and the conductor coil 41 is shown in FIG. 29.

The magnetoresistive element 40 may be kept stationary or moved relative to the substrate 21. The magentoresistive element 40 may be moved relative to the substrate 21, while the magnetic field is applied, and measure local changes in the magnetic field proximate the substrate surface.

Other embodiments are intentionally within the scope of the invention, as defined by the appended claims.

1. A method of detecting the presence of a substance to be detected on a surface of a substrate, the method comprising:
i) providing magnetic particles to the substrate for binding with the substance to be detected; and
ii) determining the presence of the substance to be detected by detecting the magnetoresistive effect of the magnetic particles bound to the substance to be detected on a magnetoresistive element positioned proximate the substrate surface.

2. The method of claim 1, comprising determining the presence of the substance to be detected by the application of an external applied magnetic field to the bound magnetic particles.

3. The method of claim 1, comprising providing the magnetic particles bound with a labelling compound, the labelling compound for allowing binding of the magnetic particles to the substance to be detected.

4. The method of claim 1 comprising providing a binding compound to the substrate to allow the substance to be detected to be bound to the substrate.

5. The method of claim 1 comprising providing magnetic particles which are substantially paramagnetic and/or ferromagnetic.

6. The method of claim 1 comprising removing excess unbound magnetic particles from the substrate surface by performing one or more of: applying a magnetic field to the substrate, and washing the substrate surface.

7. The method of claim 3 wherein the binding compound and/or the labelling compound is a monoclonal antibody.

8. The method of claim 3, wherein the labelling compound is the same as the binding compound.

9. (canceled)

10. The method of claim 1 comprising scanning the magnetoresistive element relative to the substrate surface during detecting the presence of the substance to be detected.

11. The method of claim 1 comprising performing the method directly on the substrate originally comprising the substance to be detected without prior transfer of the substance to be detected to another substrate.

12. The method of claim 1 wherein the magnetic particles have a diameter smaller than pores in the substrate surface.

13. The method of claim 1 wherein the magnetic particles have a diameter larger than pores in the substrate surface.

14. (canceled)

15. The method of claim 1 comprising using the magnetoresistive element to measure local changes in the detected magnetic field proximate the substrate surface while the external magnetic field is applied.

16. The method of claim 1, comprising providing the magnetic particles to the substrate in an analyte, the analyte comprising a suspension of the magnetic particles, the magnetic particles being labelled with molecules of a labelling compound such that at least a portion of a substance to be detected, when present in the analyte, binds to the labelling compound; and
providing the suspension of magnetic particles to the substrate surface such that molecules of the labelling compound that are not bound to the substance to be detected bind to molecules of a binding compound on the substrate surface; and
removing excess magnetic particles not bound to the substrate surface, and determining the presence of magnetic particles on the substrate surface to determine the concentration of the substance to be detected in the analyte.

17. The method of claim 1 comprising removing excess unbound magnetic particles from the substrate surface prior to determining the presence of the substance to be detected.

18. (canceled)

19. An apparatus for detecting the presence of a substance to be detected on a substrate, the apparatus comprising:
a magnetic field generator configured to apply an external magnetic field to a substrate to provide a magnetoresistive effect on a magnetic reader;
a magnetic reader comprising a magnetoresistive element, the magnetic reader being configured to determine the presence on the substrate surface of the substance to be detected by detecting the magnetoresistive effect of magnetic particles bound to the substance to be detected when the magnetic reader is proximate the bound magnetic particles.

20. (canceled)

21. The apparatus of claim 19 further comprising a substrate receiver configured to receive a substrate having magnetic particles on a surface thereof, the apparatus being configured to position the magnetoresistive element proximate the substrate surface to measure local changes in detected magnetic field proximate the substrate surface while the external magnetic field is applied.

22. The apparatus of claim 1 wherein the magnetic reader is configured to determine the presence on the substrate surface of paramagnetic particles.

23. A kit for the detection of a substance, the kit comprising:
the apparatus of any of preceding apparatus claim;
a container comprising a suspension of magnetic particles labelled with a labelling compound capable of binding to the substance to be detected.

24.-28. (canceled)

29. The method of claim 1 wherein the substrate comprises a silicon wafer.
